(19) United States
(12) Patent Application Publication
(10) Pub. No.: US 2025/0087619 A1
(43) Pub. Date: Mar. 13, 2025

(54) DISPLAY DEVICE

(71) Applicant: AUO Corporation, Hsin-Chu (TW)

(72) Inventor: Yi-Shan CHANG, Hsin-Chu (TW)

(21) Appl. No.: 18/396,823

(22) Filed: Dec. 27, 2023

(30) Foreign Application Priority Data
Sep. 8, 2023 (TW) 112134273

(51) Int. Cl. H01L 23/00; H01L 25/16

(52) U.S. Cl. CPC H01L 24/29; H01L 24/30; H01L 24/32; H01L 25/167; H01L 2224/29124; H01L 2224/29147; H01L 2224/2919; H01L 2224/30132; H01L 2224/30505; H01L 2224/32225; H01L 2924/0132

(57) ABSTRACT

A display device includes a plurality of display units, a plurality of display unit fixing members, a plurality of first adhering members and a second adhering member.

The display units are arranged in an array to function as a display surface of the display device, and a splicing area exists between two adjacent display units. The display unit fixing members are disposed on the display units. The first adhering members are disposed on the splicing area, and two ends of a corresponding first adhering member respectively contact with the two adjacent display units. The second adhering member is disposed between the corresponding first adhering member and the display unit fixing members. A portion of the second adhering member overlaps with the corresponding first adhering member.

### CROSS-REFERENCE TO RELATED PATENT APPLICATION

This non-provisional application claims priority to and the benefit of, pursuant to 35 U.S.C. § 119(a), patent application Serial No. 112134273 filed in Taiwan on Sep. 8, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to an electronic device, and particularly to a display device.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In order to meet the demand for a large display area of the display device, the spliced display using a plurality of display units has gradually become the solution for relevant manufacturers in recent years.

However, due to the limited precision in the processing capability of each component, there will be unavoidable tolerances in the size or thickness of each display unit. This causes that, when the display units are spliced and assembled with each other, the display units may be extruded from other components, resulting in horizontal offsets of varying sizes in each display unit, such that it is difficult to control the spacing between the display units. In addition to causing assembly difficulties, compared with the case where there is a fixed spacing between the light emitting components of the display units, if the spacing between the splicing areas of the display units is too large, dark lines may easily form when the display is illuminated; and if the spacing is too small, bright lines may easily form when the display is illuminated. To enhance the display quality at the location of the splicing area, there is a need to develop a method and a construction to produce a splicing display with high efficiency.

### SUMMARY

One aspect of the present disclosure provides a display device with better splicing and alignment accuracy, convenient rework, and high assembly yield.

In one embodiment of the present disclosure, the display device includes a plurality of display units, a plurality of display unit fixing members, a plurality of first adhering members and a second adhering member. The display units are arranged in an array to function as a display surface of the display device, and a splicing area exists between two adjacent display units. The display unit fixing members are disposed on the display units. The first adhering members are disposed on the splicing area, and two ends of a corresponding first adhering member respectively contact with the two adjacent display units. The second adhering member is disposed between the corresponding first adhering member and the display unit fixing members. A portion of the second adhering member overlaps with the corresponding first adhering member.

Based on the foregoing, the first adhering members of the display device according to one embodiment of the present disclosure may pre-fix the display units, such that when each display unit is laminated and assembled with other components (such as the display unit fixing members), the horizontal displacement between the display units may be reduced. On the other hand, by the matching of the second adhering member with the first adhering members, thus performing secondary fixation, further strengthening the coupling strength between each display unit and other components, and reducing the warpage of the display unit fixing members, the second adhering member may also balance the thickness of the first adhering members, such that the thickness between the display unit fixing members and the display units become more uniform. Thus, the splicing and alignment accuracy of the display device is increased, the difficulty of rework is reduced, and the assembly yield is enhanced.

The features and advantages of the present disclosure will become apparent and understandable from the embodiments taken in conjunction with the accompanying drawings in detail as follows.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1A is an exploded schematic view of a display device according to a first embodiment of the present disclosure.

FIG. 1B is a sectional schematic view of the display device of FIG. 1A along a sectional line A-A′.

FIG. 2 is an exploded schematic view of a display device according to a second embodiment of the present disclosure.

FIG. 3 is an exploded schematic view of a display device according to a third embodiment of the present disclosure.

FIG. 4 is a diagram showing the relationship between the warpage of a plurality of display unit fixing members and the spacing between different splicing areas using different first adhering members.

### DETAILED DESCRIPTION

The terms “about”, “approximately”, “essentially” or “substantially” as used herein shall cover the values described, and cover an average value of an acceptable deviation range of the specific values ascertained by one of ordinary skill in the art, where the deviation range may be determined by the measurement described and specific quantities of errors related to the measurement (that is, the limitations of the measuring system). For example, the term “about” represents within one or more standard deviations of a given value of range, such as within ±30 percent, within ±20 percent, within +15 percent, within +10 percent or within +5 percent. Moreover, the terms “about”, “approximately”, “essentially” or “substantially” as used herein may selectively refer to a more acceptable deviation range or the standard deviation based on the measuring characteristics, the cutting characteristic or other characteristics, without applying one standard deviation to all characteristics.

In the accompanying drawings, for clarity purposes, the thickness of a layer, a film, a panel, a region, etc. may be enlarged. It should be understood that when one component such as a layer, a film, a region or a substrate is referred to as being disposed “on” the other component or “connected to” the other component, the component may be directly disposed on the other component or connected to the other component, or an intermediate component may also exist between the two components. In contrast, when one component is referred to as being “directly disposed on the other component” or “directly connected to” the other component, no intermediate component exists therebetween. As used herein, a “connection” may be a physical and/or electrical connection. In addition, when two components are “electrically connected”, other components may exist between the two components.

The present disclosure will now be described hereinafter in details with reference to the accompanying drawings, in which exemplary embodiments of the disclosure are shown. Whenever possible, identical reference numerals refer to identical or like elements in the drawings and descriptions.

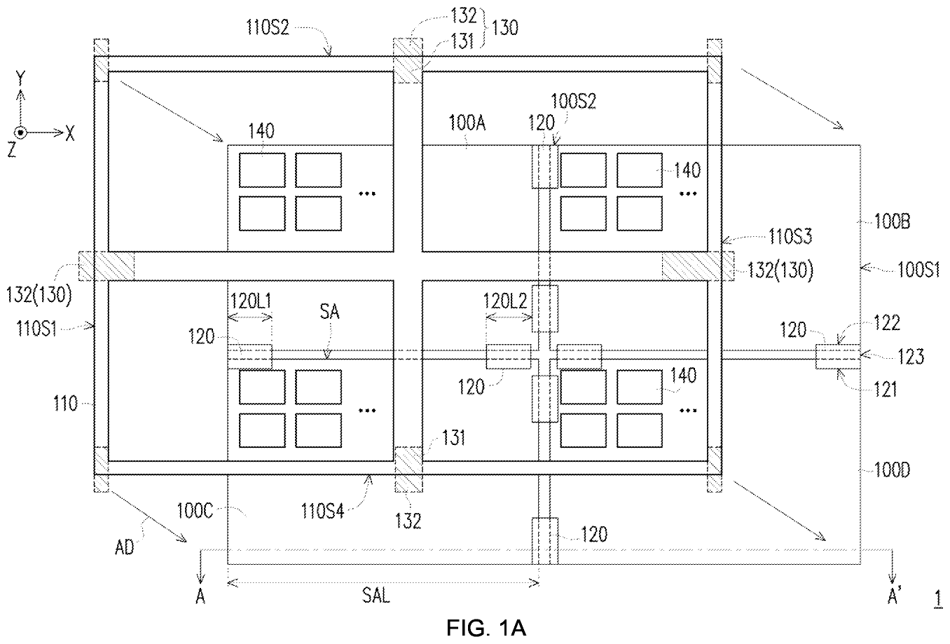

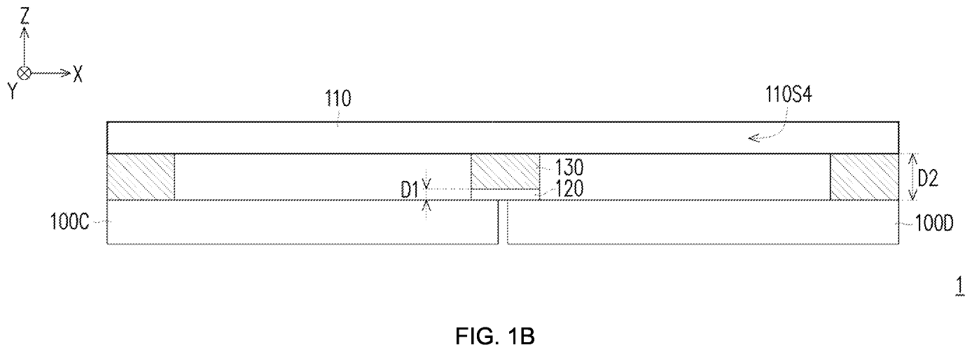

FIG. 1A is an exploded schematic view of a display device according to a first embodiment of the present disclosure. FIG. 1B is a sectional schematic view of the display device of FIG. 1A along a sectional line A-A′. Referring simultaneously to FIG. 1A and FIG. 1B, the display device 1 includes a plurality of display units (such as a display unit 100A, a display unit 100B, a display unit 100C and a display unit 100D), a plurality of display unit fixing members 110, a plurality of first adhering members 120 and a second adhering member 130. The display unit 100A, the display unit 100B, the display unit 100C and the display unit 100D are arranged in an array to function as a display surface of the display device 1. A side edge 100S1 and a side edge 10052 of the display units may serve as the edges of the display device 1, and a splicing area SA exists between two adjacent display units (such as between the display unit 100A and the display unit 100C). For convenience of illustration, the display device 1 is described to include 2*2 display units. However, the present disclosure does not limit the quantity and the arrangement of the display units. In other embodiments, the display device may include 3*4 display units, 9*16 display units or two display units, and the present disclosure is not limited thereto.

Further, the display unit 100A, the display unit 100B, the display unit 100C and the display unit 100D may respectively include a plurality of light emitting components 140. Each light emitting component 140 may be a single micro LED, a single mini LED, or a single organic LED (OLED). The structure of each light emitting component 140 may also be a formal LED, a vertical LED or a flip-chip LED, and the present disclosure is not limited thereto. In addition, the light emitting components 140 may be formed by a combination of various different types of LEDs. For example, the light emitting components 140 may include a combination of LEDs emitting red light (with a wavelength ranging from 600 nm to 700 nm), LEDs emitting green light (with a wavelength ranging from 495 nm to 590 nm) and LEDs emitting blue light (with a wavelength ranging from 420 nm to 495 nm) with various quantities. Of the light emitting components 140, the quantity ratios of each type of the LEDs may be adjusted correspondingly based on the need, and the present disclosure is not limited thereto. The light emitting components 140 may be electrically connected to each display unit 100A (or the display unit 100B, the display unit 100C and the display unit 100D) to provide the display screen image.

For example, the display unit 100A may include conductive wire redistribution layers that are alternately stacked, including a plurality of metal layers (not illustrated) and a plurality of insulating layers (not illustrated). One of the metal layers is used to form a plurality of conductive patterns, another thereof is used to form a plurality of pad patterns, and a further thereof is used to form a plurality of transfer patterns. The transfer patterns may be electrically connected to the conductive patterns and the pad patterns respectively through the contact holes of the insulating layers. That is, the metal layers may form a plurality of conductive paths that are electrically insulated from each other in the display unit 100A. The light emitting components 140 located on the display unit 100A and coupled by the conductive patterns may be electrically connected to the pad patterns respectively through the conductive paths. The display unit 100A may be electrically coupled to a driving circuit substrate (not illustrated) through the pad patterns. In other words, the driving circuit substrate includes at least one driving circuit chip IC, which has, for example, transistors or integrated circuits (ICs) that may be electrically connected to the light emitting components 140 to control the display signals of the light emitting components 140, without being limited thereto. The structures of the display unit 100B, the display unit 100C and the display unit 100D are similar to that of the display unit 100A, and are thus not herein reiterated.

The display unit fixing members 110 are disposed on the display unit 100A, the display unit 100B, the display unit 100C and the display unit 100D, and may assemble each component of the display device 1 by other clip members (not illustrated) or adhering members (such as the first adhering members 120 or the second adhering member 130). The display unit fixing members 110 may be formed by punching a whole block of the material or formed by splicing a plurality of groups of plate materials, and the present disclosure is not limited thereto. The material of the display unit fixing members 110 may include a metal plate material or plastic, and the outer edge 110S1, the outer edge 11052, the outer edge 11053 and the outer edge 11054 of the display unit fixing members 110 may serve as the edges of the display device 1, and the present disclosure is not limited thereto.

The first adhering members 120 are disposed on the splicing area SA, and a first end 121 and a second end 122 of each first adhering member 120 may respectively contact two adjacent display units. In detail, in the splicing area SA between the display unit 100B and the display unit 100D, in a projection direction of the display device 1 (such as the direction Z of FIG. 1A), each first adhering member 120 may cover the splicing area SA, and utilize the first end 121 overlapping with the display unit 100D to contact and adhere with the display unit 100D; and utilize the second end 122 overlapping with the display unit 100B to contact and adhere with the display unit 100B. Similarly, each splicing area SA between the display unit 100A and the display unit 100B, between the display unit 100A and the display unit 100C and between the display unit 100C and the display unit 100D may be respectively disposed with a plurality of first adhering members 120. For example, FIG. 1A illustrates 8 first adhering members 120, respectively disposed on the splicing areas SA between the display units, but the present disclosure does not limit the quantity of the first adhering members 120.

In other embodiments, the first adhering member 120 may further be disposed at a geometric center of the display units 100A to 100D that are arranged in a 2*2 array. For example, one end of the first adhering member 120, such as the first end 121, may respectively contact the display unit 100C and the display unit 100D; and the other end of the first adhering member 120, such as the second end 122, may respectively contact the display unit 100A and the display unit 100B. Thus, the two opposite ends of a single first adhering member 120 may be simultaneously disposed at the four display units adjacent to each other and cover the splicing area SA between the four display units adjacent to each other, and contact and pre-fix each of the four display units 100A to 100D.

Preferably, the first adhering members 120 may adopt a material having stretching resistance, flexibility and adhesion. For example, the first adhering members 120 may be, for example, single-sided tapes or double-sided tapes, which allow convenient construction in the manufacturing process and reduce the assembly cost and time. Further, compared to the implementation where the adhesive is disposed at the side edges of the display units, that is, the adhesive is disposed in the splicing area SA, using the first adhering members 120 to attach to the display units 100A to 100D may prevent from increasing the spacing of the splicing area SA. In a display with high resolution, this facilitates reducing the visibility of the splicing area SA in the display device 1.

Specifically, the first adhering members 120 may include a plastic polymer such as polyethylene terephthalate (PET) or polyimide (PI) or a composite material composed of a hybrid film of plastic polymers, but the present disclosure is not limited thereto. The first adhering members 120 may also be made of a single material or a combination of multiple materials. When the first adhering members 120 are formed by a combination of multiple materials, the stretchable material being located more adjacent to the side of the display device 1 may lead to better fixing effect of the first adhering members 120. In certain embodiments, the material of the first adhering members 120 may be a metal material with good conductivity, such as copper (Cu), aluminum (Al) or any one of an alloy thereof.

It should be noted that the edge of each first adhering member 120 is based on not exceeding the boundary of the display device 1. For example, at the right side of the display device 1, the boundary of the third end 123 of the first adhering member 120 protruding away from the display device 1 does not exceed the side edge 100S1. Similarly, at the upper side of the display device 1, the boundary of the first adhering member 120 facing away from the display device 1 does not exceed the side edge 100S2. Each first adhering member 120 disposed at the side edge of the display device 1 may adopt the configuration, without being herein reiterated. Since the first adhering members 120 do not exceed the boundary of the display device 1, when the display device 1 is required to be spliced with other display units (not illustrated), the first adhering members 120 may be prevented from adhering with the other display units, thus preventing the first adhering members 120 from affecting the spacing between the display device and the other display units.

In the thickness direction of the display device 1 (such as the direction Z), the second adhering member 130 is disposed between the first adhering members 120 and the display unit fixing members 110. In certain embodiments, the second adhering member 130 is detachable, and the first portion 131 of the second adhering member 130 overlaps with the first adhering members 120. Specifically, the second adhering member 130 may be firstly attached to a side of the display unit fixing members 110 facing toward the display units 100A to 100D, and when assembling the display device 1, in an alignment direction AD, the first portion 131 of the second adhering member 130 is aligned and attached to the first adhering members 120. There may be a plurality of second adhering members 130, and each corner of the display unit fixing members 110 are disposed with the second adhering members 130, but the present disclosure is not limited thereto. In other embodiments, the second adhering member 130 may be in a single strip, which is entirely attached in a large area to the splicing area SA. Preferably, the second adhering member 130 may be a fugitive adhesive (also known as removable adhesive or stretch tack-reducing tape). Therefore, the second adhering member 130 may reduce the adhesion with the first adhering members 120 and the adhesion with the display unit fixing members 110 by pulling, such that the second adhering member 130 is detached from the first adhering members 120.

Based on the foregoing, the first adhering members 120 may, prior to assembling the other components (such as the display unit fixing members 110), firstly adhere and pre-fix the display units 100A to 100D. Thus, even though the display units 100A to 100D have tolerances in the thickness direction, when the display unit fixing members 110 and the display units perform lamination and assembly, the first adhering members 120 may be utilized to effectively reduce the plane displacement between the display units 100A to 100D, such as the displacement in the direction X and the displacement in the direction Y in FIG. 1A, thereby enhancing the alignment accuracy of the display units 100A to 100D, and controlling the size of the spacing of the splicing area SA, thus reducing the generation of the dark lines between the display units 100A to 100D when the display device 1 is illuminated.

Further, when the display device 1 is a splicing micro LED display, the pixel spacing of the high resolution micro LED display is very small (such as 625 μm). By the pre-fixing of the first adhering members 120 and the matching of the second adhering member 130, the displacement in the direction X and the displacement in the direction Y of the display units 100A to 100D may be controlled to be within 5% of the pixel spacing (that is, the displacement in each direction may be substantially controlled to be less than 30 μm). Thus, even though viewing in a short distance or from different angles, it is difficult to observe the region where the splicing area SA exists, thus effectively enhancing the product display quality of the display device 1.

In addition, when the second adhering member 130 is attached on the first adhering members 120 and is detachable, when the display unit fixing members 110 and the display units 100A to 100D are assembled, the display unit fixing members 110 may be easy to rework if there is an error, the configuration of the second adhering member 130 may further strengthen the coupling strength between each components of the display device 1, and reduce the warpage of the display unit fixing members 110, further enhancing the alignment accuracy of each component of the display device 1, reducing the difficulty of rework, and indirectly enhancing the product yield of the display device 1. However, the present disclosure is not limited thereto, and in other embodiments, if a stronger coupling effect is considered without considering the yield factor, the second adhering member 130 may also choose a non-reworkable material.

It should be noted that the second adhering member 130, in addition to having the first portion 131 overlapping with the first adhering members 120, further has a second portion 132 not overlapping with the display unit fixing members 110 and not overlapping with the first adhering members 120. From another perspective, in a projection direction of the display unit 1, the second portion 132 of the second adhering member 130 may be exposed outside the display unit fixing members 110, without being blocked by the body portions of the display unit fixing members 110, thus facilitating the force pulling of the second adhering member 130 and allowing rework, but the present disclosure is not limited thereto.

In certain embodiments, the second portions 132 of the second adhering members 130 may respectively contact the outer edge 11051, the outer edge 11052, the outer edge 11053 and the outer edge 11054 of the adjacent display unit fixing members 110. From another perspective, the second portions 132 not blocked by the display unit fixing members 110 may bend upward toward the display surface direction (such as the direction Z) of the display device 1, and correspondingly adhere to the side edges of the display unit fixing members 110, thus facilitating the storage of the second adhering members 130 and improving the overall appearance of the display device 1.

In certain embodiments, a visible light transmittance of the first adhering members 120 may be less than 5%. The low transmittance may reduce the light leakage at the inner side of the display device 1, thus preventing the splicing area SA at the front surface of the display device 1 from unexpected light leakage. In certain embodiments, an adhesion of the first adhering members may be greater than 1 newton/cm, and when the display unit fixing members 110 have warpage and the display device 1 is assembled, the first adhering members 120 with better adhesion may facilitate maintaining the spacing of the display units (which will be described as follows).

On the other hand, to take into account that the first adhering members 120 have sufficient stretching resistance and adhesion, a suitable ratio of the attaching area to the thickness of the first adhering members 120 needs to be maintained. For example, a sum of a length 120L1 of the first adhering member 120 located between the display unit 100A and the display unit 100C and a length 120L2 of another first adhering member 120 may be less than one half of a total length SAL of the splicing area SA parallel to the direction of the length 120L1. Since the attaching ratio of the first adhering members 120 is small, the thickness D1 of each first adhering member 120 may be substantially 35 μm, and the thickness D2 of the second adhering member 130 before lamination may be substantially 200 μm. Thus, after splicing, the thickness between the display unit fixing members 110 and the display units may be formed mainly by the second adhering member 130. Since the overlapping region of the second adhering member 130, which is with elasticity and has a soft material, and the first adhering members 120 has a reduced thickness of about 10% when splicing, the total thickness of the overlapping region of the first adhering members 120 and the second adhering member 130 is 200(1-10%)+35=215 μm, which has a 7.5% difference compared to the thickness D2 of the second adhering member 130 in other regions, which is 200 μm, thus providing better thickness uniformity. Further, when the assembly generates a pressure stress, the first adhering members 120 may ensure to maintain the predetermined positions of the display units 100A to 100D, thus reducing the plane displacement in the assembling process. In certain embodiments, it is also possible not to provide excessive restrictions to the thickness D1 of the first adhering members 120, which facilitates the variety of the material options, thus reducing the material requirement of the first adhering members 120. Specifically, a ratio of a total length of the first adhering members 120 covering the splicing area SA to a total length SAL of the splicing area SA may be greater than 0.5, which may achieve the similar effect, and is thus not herein reiterated.

Certain other embodiments are enumerated to describe the present disclosure in detail, in which identical components are identified by identical reference numerals, and descriptions of the identical technical contents will be omitted. The omitted descriptions may be referenced to in the aforementioned embodiment, and are not hereinafter reiterated.

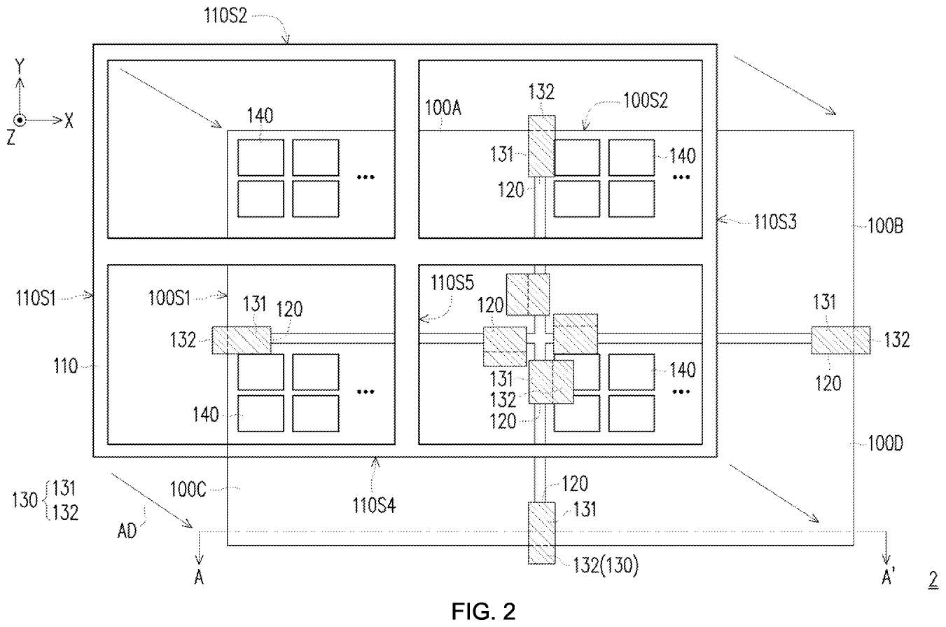

FIG. 2 is an exploded schematic view of a display device according to a second embodiment of the present disclosure. Referring to FIG. 2, the display device 2 in the present embodiment is similar to the display device 1 of FIG. 1A, and the difference thereof exists in that the configurations of the first adhering members 120 and the second adhering member 130 are different.

In detail, compared to the display device 1, where the first adhering members 120 is attached to the display units 100A to 100D, and the second adhering member 130 is disposed at the side of the display unit fixing members 110 facing toward the display units 100A to 100D, and then coupling and assembling are performed, the first adhering members 120 and the second adhering members 130 of the display device 2 may be combined and cut according to the required size, and then jointly attached to the splicing area SA of the display units 100A to 100D. From another perspective, in the display device 2, the quantity of the second adhering members 130 may be equal to the quantity of the first adhering members 120, thus reducing the alignment requirement between the first adhering members 120 and the second adhering members 130, and facilitating the assembly of the display device 2.

Similar to the foregoing, to prevent the second adhering members 130 from blocking the light emitting components 140 of the display units 100A to 100D, the second portion 132 of the second adhering member 130 located at the center of the display device 2 (for example, FIG. 2 exemplarily illustrates 4 second adhering members 130 disposed on the first adhering members 120 at the center of the display device 2) may bend upward toward the thickness direction of the display unit fixing members 110, and be attached to the inner edge 110S5 of the display unit fixing members 110.

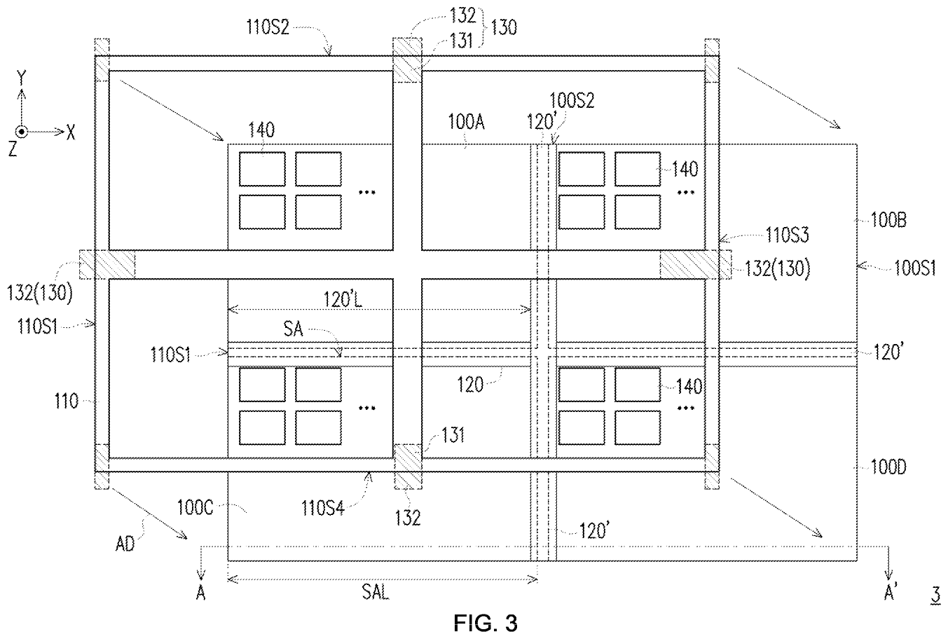

FIG. 3 is an exploded schematic view of a display device according to a third embodiment of the present disclosure. Referring to FIG. 3, the display device 3 in the present embodiment is similar to the display device 1 of FIG. 1A, and the difference thereof exists in that the configurations of the first adhering members 120′ are different.

In the display device 3, the first adhering members 120′ may be entirely attached on the splicing area SA of the display device 3, and completely cover the splicing area SA between the display units 100A to 100D. That is, in the projection of the display device 3, a ratio of a total length 120′L of the first adhering members 120′ covering the splicing area SA to a total length SAL of the splicing area is substantially 1. By the first adhering members 120′ completely covering the splicing area SA in a large area, it is conducive to increasing the overall structural stability of the display device 3 and the accuracy control in the assembling process.

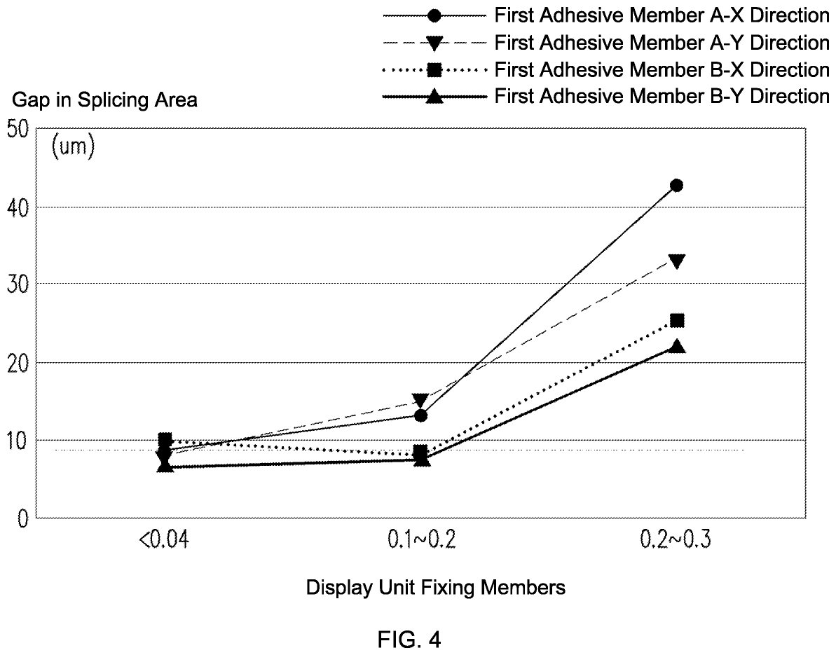

FIG. 4 is a diagram showing the relationship between the warpage of a plurality of display unit fixing members and the spacing between different splicing areas using different first adhering members. Referring to FIG. 4, the examination adopts different first adhering member A and first adhering member B, and for the case where the display unit fixing members 110 have different degrees of warpage (such as the horizontal axis parameter in the figure), the spacing values of the splicing area SA in the direction X and direction Y in the display device 1 are measured. The adhesion of the first adhering member A is substantially 2.7 newton/cm, and the thickness thereof is about 60 μm, and the adhesion of the first adhering member B is substantially 7.5 newton/cm, and the thickness thereof is about 100 μm. It may be observed that, in the case where the first adhering member A and the first adhering member B have the same attachment area in the display device 1, using the first adhering member B with better adhesion may achieve smaller splicing values of the splicing area SA in the direction X and the direction Y under the condition that the display unit fixing members 110 have the same warpage. In the case where the display unit fixing members 110 have the increasing warpage, the first adhering member B with better adhesion may facilitate maintaining the spacing of the splicing area SA, thus reducing the displacement of the display units 100A to 100D. Accordingly, the higher the viscosity of the first adhering members 120 becomes, the better it may resist the tolerance warpage issues.

In sum, the first adhering members of the display device according to one embodiment of the present disclosure may pre-fix the display units, such that when each display unit is laminated and assembled with other components (such as the display unit fixing members), the horizontal displacement between the display units may be reduced. On the other hand, by the matching of the second adhering member with the first adhering members, thus further strengthening the coupling strength between each display unit and other components, and reducing the warpage of the display unit fixing members, the second adhering member may also balance the thickness of the first adhering members, such that the thickness between the display unit fixing members and the display units become more uniform. Thus, the splicing and alignment accuracy of the display device is increased, the difficulty of rework is reduced, and the assembly yield is enhanced.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display device, comprising:
a plurality of display units, arranged in an array to function as a display surface of the display device, wherein a splicing area exists between two adjacent display units of the display units;
a plurality of display unit fixing members, disposed on the display units;
a plurality of first adhering members, disposed on the splicing area, wherein two ends of a corresponding first adhering member of the first adhering members respectively contact with the two adjacent display units; and
a second adhering member, disposed between the corresponding first adhering member and the display unit fixing members, wherein a portion of the second adhering member overlaps with the corresponding first adhering member.

2. The display device according to claim 1, wherein a material of the first adhering members comprises a plastic polymer or a hybrid film of a plastic polymer.

3. The display device according to claim 1, wherein a material of the first adhering members comprises copper, aluminum or any one of an alloy thereof.

4. The display device according to claim 1, wherein a visible light transmittance of the first adhering members is less than 5%.

5. The display device according to claim 1, wherein an adhesion of the first adhering members is greater than 1 newton/cm.

6. The display device according to claim 1, wherein a ratio of a total length of the first adhering members covering the splicing area to a total length of the splicing area is greater than 0.5.

7. The display device according to claim 1, wherein another portion of the second adhering member does not overlap with the display unit fixing members.

8. The display device according to claim 1, wherein another portion of the second adhering member contacts outer edges of the display unit fixing members.

9. The display device according to claim 1, wherein the display units comprise a plurality of light emitting components, wherein each of the light emitting components is one of a light emitting diode (LED), a micro LED or an organic LED.

10. The display device according to claim 1, wherein the display units further comprise four display units arranged in a 2*2 array, the first adhering members further comprise another first adhering member disposed at a geometric center of the four display units, and the another first adhering member contacts each of the four display units.

11. The display device according to claim 1, wherein the second adhering member is detachable.
